(19) United States
(12) Patent Application Publication
(10) Pub. No.: US 2011/0278164 A1
(43) Pub. Date: Nov. 17, 2011

(54) SPUTTERING DEVICE

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/860,916

(22) Filed: Aug. 22, 2010

(30) Foreign Application Priority Data
May 12, 2010 (TW) 99115204

(51) Int. Cl. C23C 14/34

(52) U.S. Cl. 204/298.07

(57) ABSTRACT

A sputtering device includes a chamber having a number of targets mounted therein, a supporting frame, and a gas supplying frame. The chamber defines an engaging hole and a gas input hole therein. The supporting frame is capable of having a revolution in the chamber, the supporting frame includes a number of supporting poles for supporting workpieces, and the supporting poles is capable of having a rotation relative to the supporting frame. The gas supplying frame is received in the supporting frame, the gas supplying frame includes a gas input pipe engaging in and extending through the engaging hole of the chamber, and a number of gas guiding pipes are in communication with the gas input pipe and are substantially parallel with the supporting poles. Each of the gas guiding pipes has a number of gas output holes around the workpieces.

### BACKGROUND

1. Technical Field

The present disclosure relates to a sputtering device.

2. Description of Related Art

Sputtering deposition is a physical vapor deposition (PVD) method of depositing thin films by sputtering, that is ejecting material from a target acting as a gas source, which then deposits onto a workpiece, such as a substrate or a wafer.

In a reaction sputtering deposition, at least one reactive gas such as O₂N₂ or C₂H₂ is input into a reaction chamber where targets and workpieces to be sputtered are located. The reactive gas reacts with the material of the targets which is bombarded out by a working gas, to form a reaction compound film on the workpieces. In a typical reaction sputtering deposition, the reactive gas is mixed with the working gas beforehand, and then the mixed gases are input into a reaction chamber through a pipe connected to the reaction chamber.

However, with the above configuration, the reaction chamber usually fails to have a uniform gas concentration therein. In addition, all of the gases are input into the reaction chamber synchronously, thus the reaction chamber lacks a working gas environment before the sputtering deposition.

What is needed, therefore, is a sputtering device, which can overcome the above shortcomings.

### BRIEF DESCRIPTION OF THE DRAWINGS

Many aspects of the present sputtering device can be better understood with reference to the following drawings. The components in the drawings are not necessarily drawn to scale, the emphasis instead being placed upon clearly illustrating the principles of the present sputtering device. Moreover, in the drawings, like reference numerals designate corresponding parts throughout the several views.

FIG. 1 is a disassembled, schematic view of a sputtering device in accordance with an exemplary embodiment, the sputtering device including a chamber, a supporting frame and a gas supplying frame.

FIG. 2 is a cross sectional view of the chamber of FIG. 1.

FIG. 3 is an enlarged view of the supporting frame of FIG. 1.

FIG. 4 is an assembled view of the supporting frame and the gas supplying frame of FIG. 1.

FIG. 5 is an assembled view of the chamber, the supporting frame and the gas supplying frame of FIG. 1.

### DETAILED DESCRIPTION

Embodiments of the present sputtering device will now be described in detail below and with reference to the drawings.

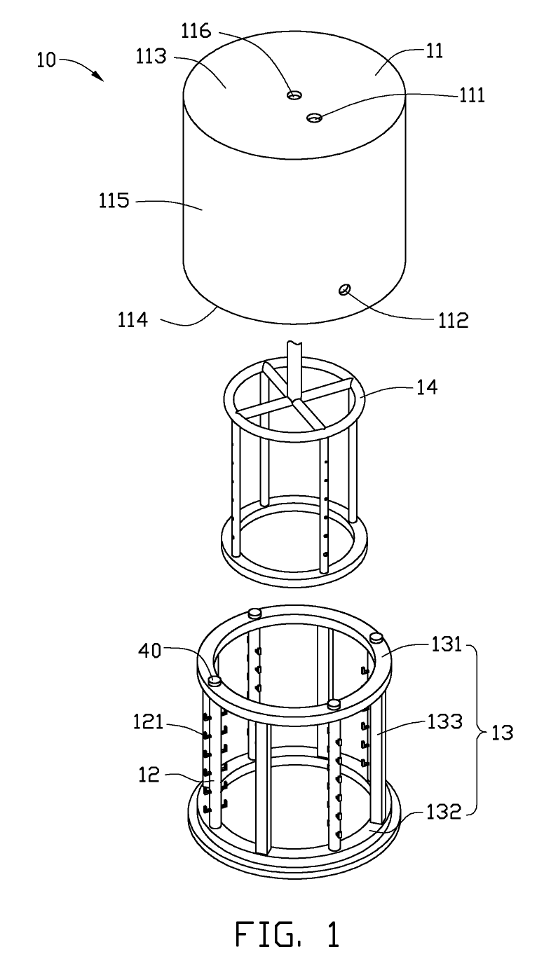

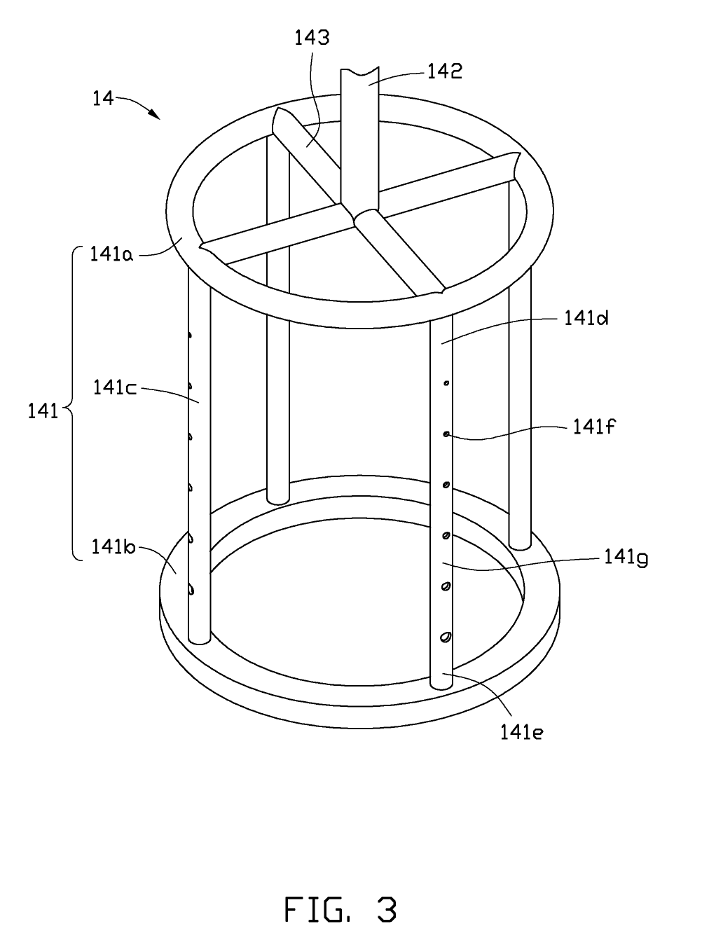

Referring to FIGS. 1 to 3, a sputtering device 10 for sputtering deposition is provided. The sputtering device 10 includes a chamber 11, a supporting frame 13 and a gas supplying frame 14. The chamber 11 receives the supporting frame 13 and the gas supplying frame 14 therein.

The chamber 11 is in a cylindrical shape. The chamber 11 is structured by a top plate 113, a bottom plate 114 and a peripheral sidewall 115. The bottom plate 114 is fastened with the peripheral sidewall 115 to be opened, thus the supporting frame 13 and the gas supplying frame 14 can be taken out off the chamber 11. The top plate 113 has an engaging hole 116 defined in a center thereof, and a gas input hole 111 defined therein. The sidewall 115 has a gas evacuating hole 112 defined therein. The gas evacuating hole 112 is arranged near the bottom plate 114, and configured for evacuating gas in the chamber 11 before or after a sputtering deposition. The gas evacuating hole 112 can be closed during the sputtering deposition.

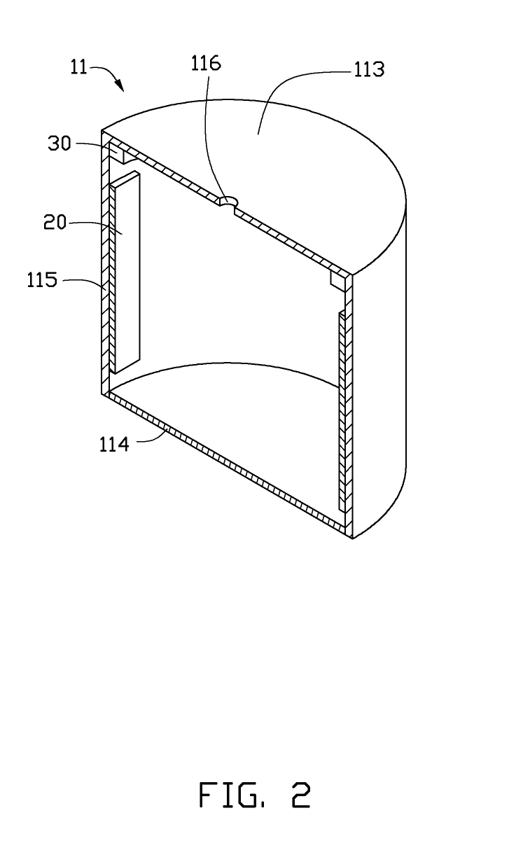

A number of targets 20 are mounted on the peripheral sidewall 115 inside the chamber 11 (see FIG. 2).

The supporting frame 13 includes a top ring 131, a bottom ring 132, and a number of posts 13 and supporting poles 12 located between the top ring 121 and the bottom ring 132. The top ring 131, the bottom ring 132 and the posts 13 each are solid. The supporting poles 12 are spaced apart by the posts 13. The supporting poles 12 are parallel with each other and rotatably engaged with the top ring 121 and the bottom ring 132. Each of the supporting poles 12 has a number of shelves 121 formed thereon. The shelves 121 are spaced apart from each other and each are configured for carrying a workpiece to be sputtered.

The gas supplying frame 14 includes a retaining frame 141, a gas input pipe 142 and a number of gas distributing pipes 143. The retaining frame 141 includes a ring-shaped gas flowing pipe 141a, a number of gas guiding pipes 141c, and a ring-shaped base 141b. Each of the gas guiding pipes 41c includes a gas input end 141d in communication with the gas flowing pipe 141a, and an opposite sealing end 141e fixed to the base 141b. A number of gas output holes 141f are formed in sidewall 141g of the gas guiding pipe 141c. The gas output holes 141f are arranged at a line, and are spaced apart from each other. Diameters of the gas output holes 141f gradually increase from the gas input end 141d to the sealing end 141e.

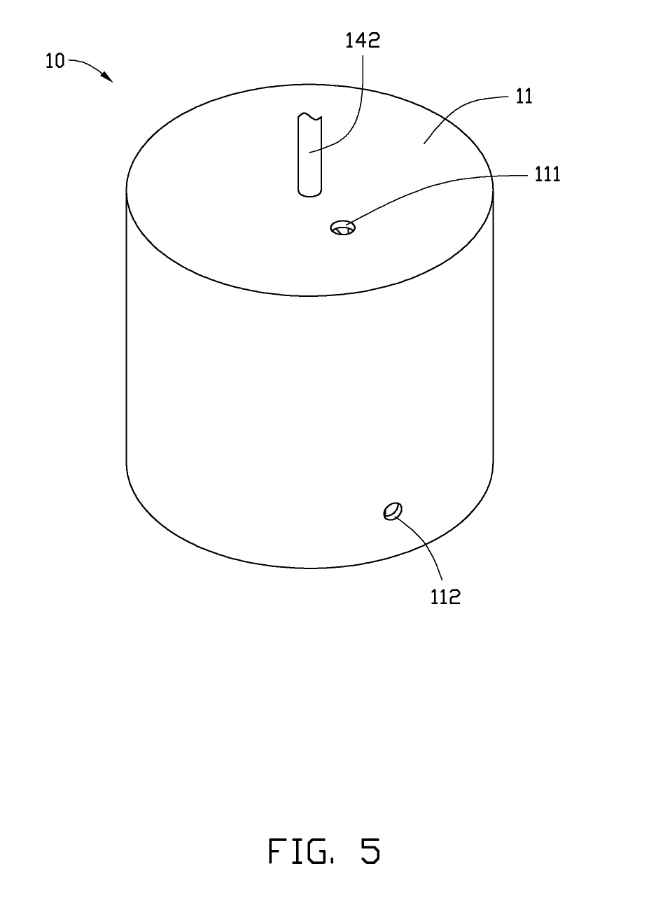

The gas input pipe 142 is engaged in and extends through the engaging hole 116 of the chamber 11 (see FIG. 5). The gas input pipe 142 is in communication with the gas flowing pipe 141a by a number of gas distributing pipes 43. The gas distributing pipes 43 are arranged at a same plane. The number of the gas distributing pipes 43 is the same as the number of the gas guiding pipes 141c, and an end of each of the gas distributing pipes 43 is adjacent to an end of a corresponding gas guiding pipe 141c.

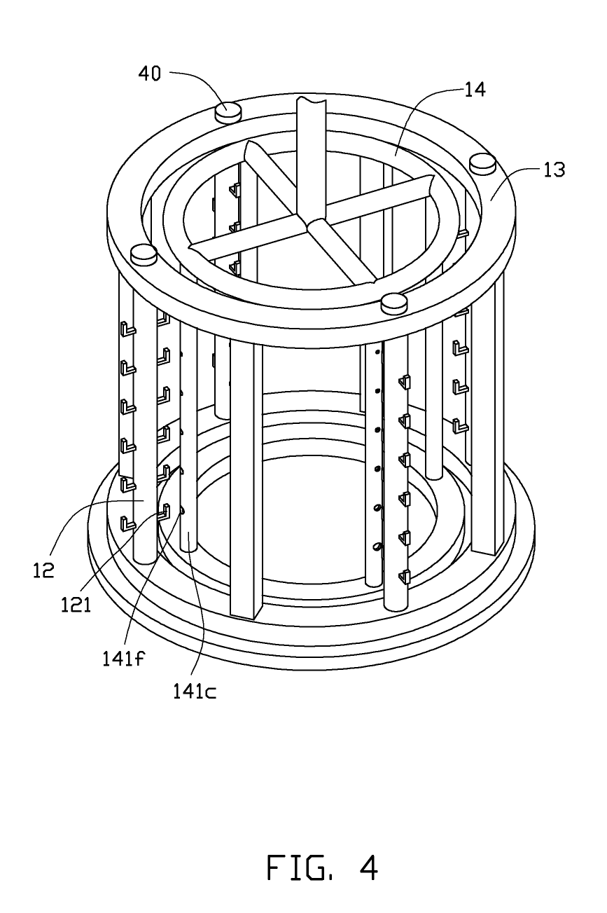

The gas supplying frame 14 is received in the supporting frame 13 (see FIG. 4). The gas guiding pipes 141c are substantially parallel with the supporting poles 12, and the gas output holes 141f around the shelves 121. The gas input pipe 142, the gas flowing pipe 141a and the gas guiding pipes 141c form a long-way gas supplying system.

In application, the supporting frame 13 revolves about the central axis thereof, and each of the supporting poles 12 rotates about the central axis thereof. A driving apparatus 30 for driving the supporting frame 13 can be mounted on the top plate 113 inside the chamber 11, and a driving apparatus 40 for driving each of the supporting poles 12 can be mounted in the top ring 131 of the supporting frame 13. A first gas is input into the chamber 11 from the gas input hole 111, and a second gas is input into the gas input pipe 142. The first gas can only be a working gas such as an inert gas to form a plasma area above the target 20 under an electric field. The second gas can be a reactive gas such as O₂ to react with the material of the targets 20 bombarded out in the plasma area by the working gas, to form a reaction compound depositing on the workpieces on the shelves 121. The working gas can be first input into the chamber 11 without any electric field applied before the reactive gas is input into the chamber 11.

Each of the first and second gases may be a mixed gas. The long-way gas supplying system ensures the second gas is directly input to almost everywhere in the chamber 11, thus a more uniform gas concentration can be achieved.

It is understood that the above-described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A sputtering device, comprising:
a chamber having a plurality of targets mounted therein, the chamber defining an engaging hole and a gas input hole;
a supporting frame revolvably received in the chamber, the supporting frame comprising a plurality of supporting poles for supporting workpieces, the supporting poles being rotatable relative to the supporting frame, the supporting frame being revolvable relative to the chamber; and
a gas supplying frame received in the supporting frame, the gas supplying frame comprising a gas input pipe engaging in and extending through the engaging hole of the chamber, and a plurality of gas guiding pipes in communication with the gas input pipe and parallel with the supporting poles, each of the gas guiding pipes comprising a plurality of gas output holes, diameters of the gas output holes increasing with increasing distance away from the gas input pipe.

2. The sputtering device of claim 1, wherein the chamber comprises a top plate, a bottom plate and a peripheral sidewall between the top plate and the bottom plate, the targets being mounted on the sidewall inside the chamber, the engaging hole and the gas input hole being defined in the top plate.

3. The sputtering device of claim 2, wherein the chamber further defines a gas evacuating hole in the sidewall adjacent to the bottom plate.

4. The sputtering device of claim 1, wherein the supporting frame further comprises a top ring and a bottom ring, the supporting poles located between the top ring and the bottom ring, and each of the supporting poles comprising a plurality of shelves formed thereon, the shelves configured for carrying the workpieces.

5. The sputtering device of claim 1, wherein the gas supplying frame further comprises ring-shaped gas flowing pipe and a ring-shaped base, the gas flowing pipe in communication with the gas input pipe, the gas guiding pipes located between the gas flowing pipe and the base, the gas guiding pipes in communication with the gas flowing pipe and terminating at the base.

6. The sputtering device of claim 5, wherein the gas supplying frame further comprises a plurality of gas distributing pipes corresponding to the gas guiding pipes, the gas distributing pipes interconnecting the gas input pipe and the gas flowing pipe, and an end of each of the gas distributing pipes adjacent to an end of the corresponding gas guiding pipe.

7. The sputtering device of claim 6, wherein the gas distributing pipes are arranged at a same plane.

8. The sputtering device of claim 1, further comprising a first driving apparatus for driving the supporting frame to revolve, and a second driving apparatus for driving the supporting poles to rotate.

9. A sputtering device, comprising:
a chamber having a plurality of targets mounted therein, the chamber defining an engaging hole and a gas input hole therein;
a supporting frame capable of revolving in the chamber, the supporting frame comprising a plurality of supporting poles for supporting workpieces, the supporting poles capable of rotating relative to the supporting frame; and
a gas supplying frame received in the supporting frame, the gas supplying frame comprising a gas input pipe engaging in and extending through the engaging hole of the chamber, and a plurality of gas guiding pipes in communication with the gas input pipe and parallel with the supporting poles, each of the gas guiding pipes comprising a plurality of gas output holes around the workpieces.

10. The sputtering device of claim 9, wherein diameters of the gas output holes gradually increase as increasing distance away from the gas input pipe.

11. The sputtering device of claim 9, wherein the supporting poles are parallel to each other.
